(19) United States
(12) Patent Application Publication
(10) Pub. No.: US 2008/0157287 A1
(43) Pub. Date: Jul. 3, 2008

(54) Semiconductor devices and methods of forming the same

(75) Inventors: Ju-Il Choi, Suwon-si (KR); Cha-Jea Jo, Suwon-si (KR); Seok-Ho Kim, Bucheon-si (KR); Chang-Woo Shin, Gunpo-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/003,798

(22) Filed: Jan. 2, 2008

(30) Foreign Application Priority Data
Jan. 2, 2007 (KR) 10-2007-0000240

(51) Int. Cl. H01L 21/768; H01L 23/48

(52) U.S. Cl. 257/621; 438/667; 257/E21.585; 257/E23.011

(57) ABSTRACT

A semiconductor device and methods of forming the same are provided. The methods may include forming a hole in a preliminary semiconductor substrate, forming an insulating layer in the hole of the preliminary semiconductor substrate, forming a plating conductive layer on the insulating layer and the preliminary semiconductor substrate, forming a seed metal layer contacting the plating conductive layer at a lower portion of the hole and growing the seed metal layer to form a through-silicon via (TSV). The TSV may be formed through an electroplating process such that the seed metal layer grows from the lower portion of the hole to an upper portion of the hole.

### PRIORITY STATEMENT

This U.S. non-provisional patent application claims the benefit of priority under 35 U.S.C. §119 from Korean Patent Application No. 10-2007-0000240, filed on Jan. 2, 2007, the entire contents of which are hereby incorporated by reference.

### BACKGROUND

1. Field

Example embodiments relate to a semiconductor devices and methods of forming the same. Other example embodiments relate to a semiconductor device having a through-silicon via (TSV) and methods of forming the same.

2. Description of Related Art

Packaging technology for integrated circuits in the semiconductor industry is undergoing increased development in order to satisfy a need for miniaturization and/or mounting reliability. The need for miniaturization is pushing the packaging technology to develop a package size that substantially corresponds to semiconductor chip size.

Among the packaging technologies for miniaturization, a wafer level package is desirable. The wafer level package has excellent thermal and electrical properties. The wafer level package may be tested in a wafer state. Fabrication of the package requires no additional costs. The wafer level package may have a through-silicon via (TSV), which electrically connects semiconductor chips, external circuits and stacked chip packages to each other.

FIGS. 1A and 1B are diagrams illustrating sectional views of a method of forming a conventional semiconductor device;

Referring to FIG. 1A, a hole 15 may be formed in a semiconductor substrate 10. A seed metal layer 20 may be formed on the semiconductor substrate 10 having the hole 15. An insulating layer (not shown) may be interposed between the seed metal layer 20 and the semiconductor substrate 10 with the hole 15.

Referring to FIG. 1B, a photoresist pattern 30 may be formed on the seed metal layer 20 exposing the hole 15. The seed metal layer 20 may be grown by performing an electroplating process to form a through-silicon via (TSV) 40.

In the electroplating process, an electric current may be concentrated on the seed metal layer 20 disposed (or formed) over the hole 15 such that the TSV 40 may over grow. The overgrowth may cause a void (V) and a recessed top surface (C) to form in the TSV, deteriorating the electrical properties of the semiconductor device.

### SUMMARY

Example embodiments relate to a semiconductor devices and methods of forming the same. Other example embodiments relate to a semiconductor device having a through-silicon via (TSV) and methods of forming the same.

Example embodiments provide a semiconductor device having increased electrical properties and a method of forming the same.

Example embodiments provide a semiconductor device including a through-silicon via (TSV) penetrating a semiconductor substrate, wherein the TSV protrudes from a bottom surface of the semiconductor substrate; an insulating pattern between the TSV and the semiconductor substrate; and a plating conductive pattern between the insulating pattern and the TSV, wherein the TSV includes a seed metal layer at a lower portion thereof.

According to example embodiments, the semiconductor devices may include a bonding metal layer on the TSV.

The insulating pattern may include silicon nitride (e.g., a silicon nitride compound).

The seed metal layer may include at least one selected from the group consisting of copper, nickel and gold.

According to example embodiments, the methods of forming a semiconductor device may include forming a hole in a preliminary semiconductor substrate, forming an insulating layer in the hole of the preliminary semiconductor substrate, forming a plating conductive layer on the insulating layer and the preliminary semiconductor substrate, forming a seed metal layer contacting the plating conductive layer at a lower portion of the hole and growing the seed metal layer to form a through-silicon via (TSV).

Forming the seed metal layer at the lower portion of the hole may include forming a lift-off resist layer on the plating conductive layer, forming a photoresist layer on the lift-off resist layer, patterning the lift-off resist layer and the photoresist layer to form a lift-off resist pattern and a photoresist pattern, respectively, wherein the lift-off resist pattern and the photoresist pattern expose the hole. The seed metal layer may be formed on the photoresist pattern.

The photoresist pattern and the lift-off resist pattern may have an opening with a smaller width than the hole. The seed metal layer may be formed at a lower portion of the hole exposed by the opening using a sputtering process.

According to examples embodiments, the methods may include removing the lift-off resist pattern after the forming of the seed metal layer. The lift-off resist pattern may be removed by removing the photoresist pattern and removing the seed metal layer on the photoresist pattern.

According to example embodiments, forming the seed metal layer at the lower portion of the hole may include forming a preliminary seed metal layer on the plating conductive layer and performing a spin etching process on the preliminary seed metal layer. The spin etching process may be performed using an etchant having an etch selectivity with respect to the preliminary seed metal layer.

The through-silicon via (TSV) may be formed by performing an electroplating process to grow the seed metal layer from the lower portion of the hole to an upper portion of the hole.

The methods may include etching a backside of the preliminary semiconductor substrate to form a semiconductor substrate with the TSV protruding from the semiconductor substrate, after forming the TSV. The insulating layer and the plating conductive layer on the protruded TSV may be etched to form an insulating pattern and a plating conductive pattern. The plating conductive layer may have an etch selectivity with respect to the TSV.

The methods may further include forming a bonding metal layer on the TSV.

### BRIEF DESCRIPTION OF THE DRAWINGS

Example embodiments will be more clearly understood from the following detailed description taken in conjunction with the accompanying drawings. FIGS. 1-5 represent non-limiting, example embodiments as described herein.

FIGS. 1A and 1B are diagrams illustrating sectional views of a method of forming a conventional semiconductor device;

FIGS. 2A through 2H are diagrams illustrating sectional views of a method of forming a semiconductor device according to example embodiments;

FIGS. 3A through 3F are diagrams illustrating sectional views of a method of forming a semiconductor device according to example embodiments; and

FIGS. 4 and 5 are diagrams illustrating sectional views of a semiconductor device according to example embodiments.

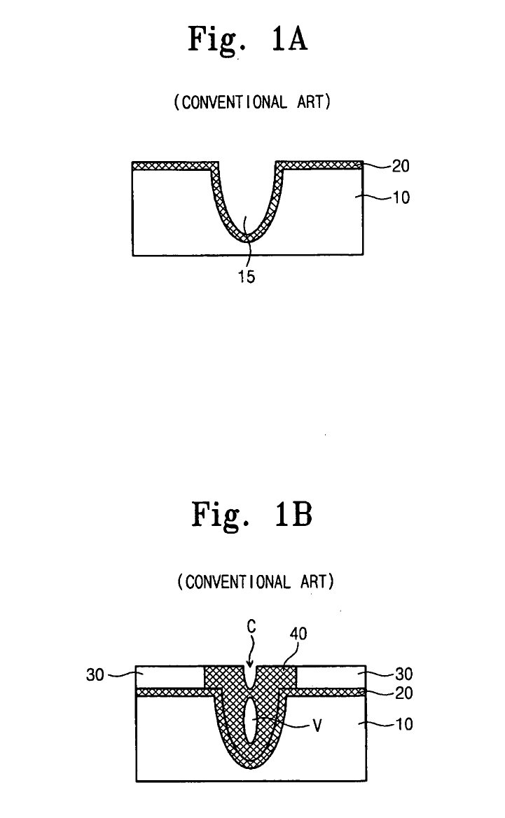

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to example embodiments described.

Example embodiments relate to a semiconductor devices and methods of forming the same. Other example embodiments relate to a semiconductor device having a through-silicon via (TSV) and methods of forming the same.

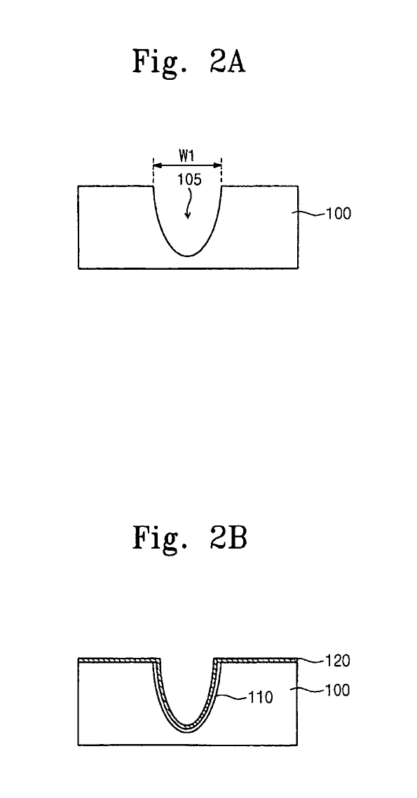

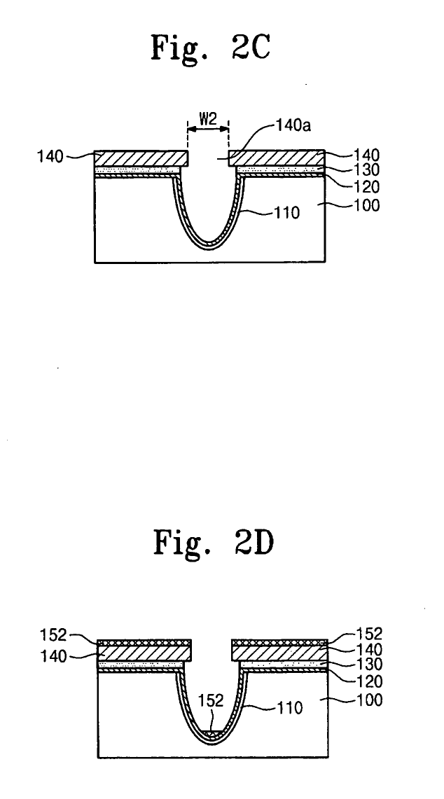

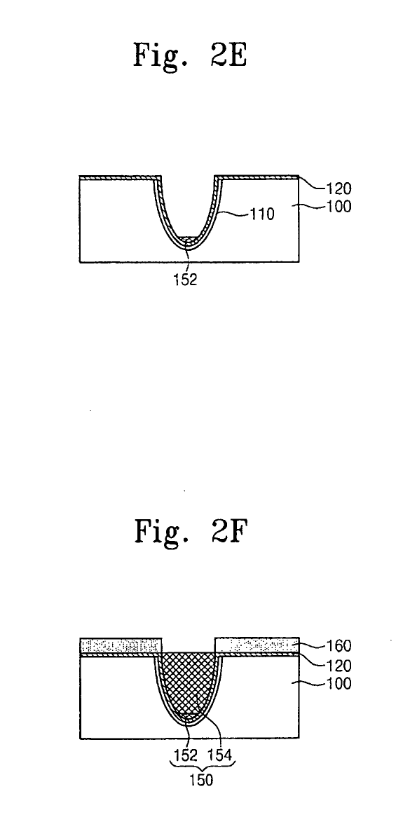

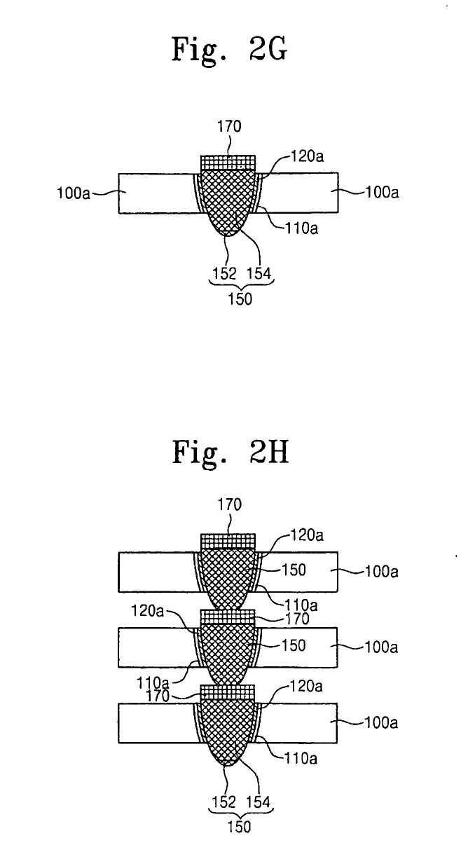

FIGS. 2A through 2H are diagrams illustrating sectional views of a method of forming a semiconductor device according to example embodiments.

Referring to FIG. 2A, a preliminary semiconductor substrate 100 is prepared. The preliminary semiconductor substrate 100 may include a semiconductor chip (not shown) having bonding pads. A hole 105 may be formed in the preliminary semiconductor substrate 100. The hole 105 may be formed through a plasma etching process or a laser drilling method. The hole 105 may have a width W1.

Referring to FIG. 2B, an insulating layer 110 may be formed in the hole 105 of the substrate 100. The insulating layer 110 may be formed through a chemical vapor deposition (CVD) or a physical vapor deposition (PVD). The insulating layer 110 may be formed of silicon nitride, silicon oxide, polymer or tantalum nitride. A plating conductive layer 120 may be formed on the insulating layer 110 and the preliminary semiconductor substrate 100. The plating conductive layer 120 may apply an electric current to a seed metal layer (discussed below).

Referring to FIG. 2C, a lift-off resist layer (not shown) may be formed on the plating conductive layer 120. The lift-off resist layer may be formed of a material which does not have photosensitivity but is soluble in a developer. A first photoresist layer (not shown) may be formed on the lift-off resist layer. A photolithography process may be performed on the first photoresist layer and the lift-off resist layer to form a first photoresist pattern 140 and a lift-off resist pattern 130, respectively. The first photoresist pattern 140 and the lift-off resist pattern 130 may expose the hole 105. The first photoresist pattern 140 may have an opening 140a exposing the hole 105. The opening 140a may have a width W2. The width W2 may be less than the width W1 of the hole 105.

Referring to FIG. 2D, a seed metal layer 152 may be formed on the first photoresist pattern 140 and the plating conductive layer 120 at the bottom of the hole 105. The seed metal layer 152 may be formed through a sputtering process. If the width W2 of the opening 140a is less than the width W1 of the hole 105, formation of the seed metal layer 152 on the plating conductive layer 120 at sides of the hole 105 may be prevented. The seed metal layer 152 may be formed of copper (Cu), nickel (Ni) or gold (Au).

Referring to FIG. 2E, the lift-off resist pattern 130 may be removed from the preliminary semiconductor substrate 100. The process of removing the lift-off resist pattern 130 may include removing the first photoresist pattern 140 and removing the seed metal layer 152 on the first photoresist pattern 140.

Referring to FIG. 2F, a second photoresist pattern 160 may be formed to expose the hole 105. The second photoresist pattern 160 may prevent formation of a plating layer on the plating conductive layer 120 outside the hole 105. A through-silicon via (TSV) 150 may be formed in the hole 105 through an electroplating process. The TSV 150 may grow upwardly from the seed metal layer 152. The TSV 150 may include the seed metal layer 152 and a growth layer 154.

Referring to FIG. 2G, the second photoresist pattern 160 and the plating conductive layer 120 formed outside the hole 105 may be removed from the preliminary semiconductor substrate 100. A backside of the preliminary semiconductor substrate 100 may be etched to form a semiconductor substrate 100a. The preliminary semiconductor substrate 100 may be etched such that the TSV 150 protrudes from the semiconductor substrate 100a. Etching the backside of the preliminary semiconductor substrate 100 may include performing a chemical mechanical polishing (CMP) process and a wet etching process. The CMP process may be performed prior to the wet etching process in order to reduce processing time.

The insulating layer 110 and the plating conductive layer 120 on the protruded TSV 150 may be etched to form an insulating pattern 110a and a plating conductive pattern 120a, respectively. The plating conductive layer 120 may have an etch selectivity with respect to the TSV 150. If the plating conductive layer 120 has an etch selectivity with respect to the TSV 150, the plating conductive layer 120 may be etched while etching of the TSV 150 is minimal, or vice-versa.

A bonding metal layer 170 may be formed on the TSV 150. The bonding metal layer 170 may be formed of eutectic metal or mixture (e.g., SnAgCu, InAu or the like). The bonding metal layer 170 may electrically connect TSVs 150 of chip packages to each other.

Referring to FIG. 2H, semiconductor chip packages including the TSV 150 may be stacked. The TSV 150 may be electrically connected to a bonding pad of the semiconductor chip package. The TSVs 150 of the semiconductor chip packages may be connected to each other via the bonding metal layer 170. Because the bonding metal layer 170 may be formed of an eutectic metal (or mixture) having a low melting point, the semiconductor chip packages may be stacked at a substantially low processing temperature.

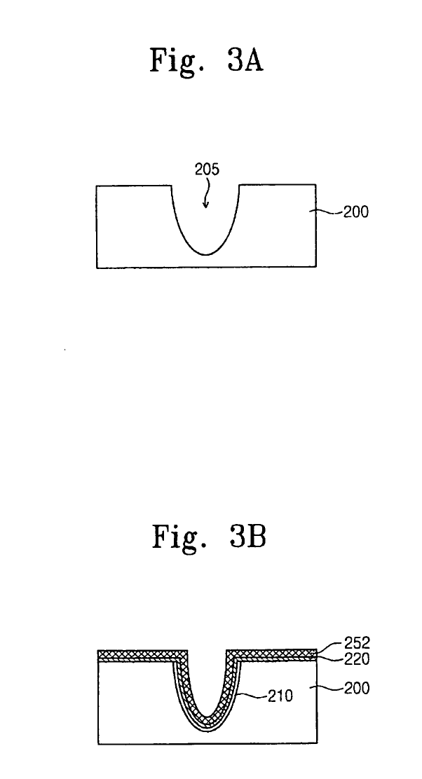

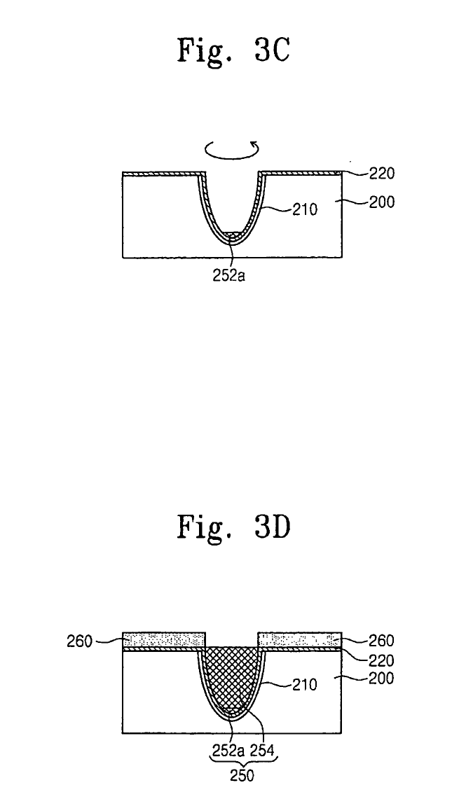

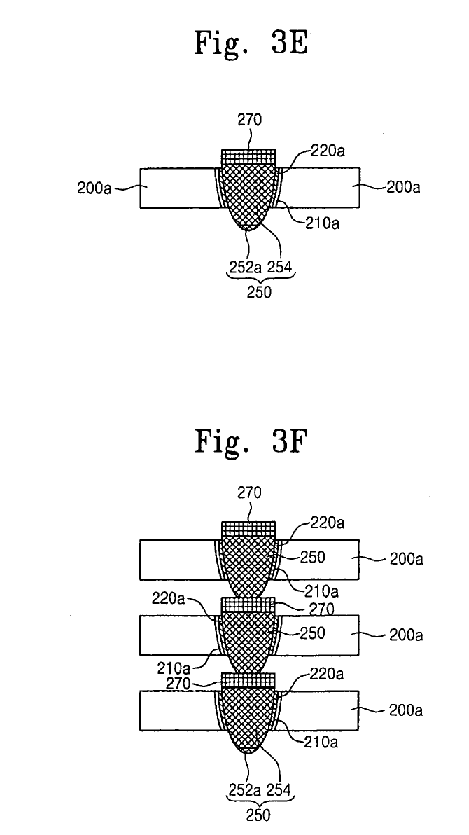

FIGS. 3A through 3A are diagrams illustrating sectional views of a method of forming a semiconductor device according to example embodiments.

Referring to FIG. 3A, a preliminary semiconductor substrate 200 is prepared. The preliminary semiconductor substrate 200 may include a semiconductor chip (not shown) having bonding pads. A hole 205 may be formed in the preliminary semiconductor substrate 200. The hole 205 may be formed by performing a plasma etching process or a laser drilling method.

Referring to FIG. 3B, an insulating layer 210 may be formed in the hole 205 of the substrate 200. The insulating layer 210 may be formed through a chemical vapor deposition (CVD) or a physical vapor deposition (PVD). The insulating layer 210 may be formed of silicon nitride, silicon oxide, polymer or tantalum nitride.

A plating conductive layer 220 may be formed on the insulating layer 210 and the preliminary semiconductor substrate 200. An electric current may be applied to a seed metal layer (described below) via the plating conductive layer 220. A preliminary seed metal layer 252 may be formed on the plating conductive layer 220. The preliminary seed metal layer 252 may be formed by performing a sputtering or a CVD process.

Referring to FIG. 3C, a spin etching process may be performed on the preliminary seed metal layer 252 to form a seed metal layer 252a. The spin etching process may include supplying an etchant to the preliminary semiconductor substrate 200 while the preliminary semiconductor substrate 200 is spinning. The preliminary seed metal layer 252 may have an etch selectivity with respect to the plating metal layer 220. For example, if the preliminary seed metal layer 252 includes copper (Cu) and the plating conductive layer 220 includes titanium (Ti), the etchant may include sulfuric acid (H₂SO₄), hydrogen peroxide (H₂O₂), which may selectively etch the preliminary seed metal layer 252.

Referring to FIG. 3D, a third photoresist pattern 260 may be formed to expose the hole 205. The third photoresist pattern 260 may prevent the formation of a plating layer on the plating conductive layer 220 outside the hole 205. A through-silicon via (TSV 250) may be formed in the hole 205 through an electroplating process. The TSV 250 may grow upwardly from the seed metal layer 252. The TSV 250 may include the seed metal layer 252a and a growth layer 254.

Referring to FIG. 3E, the third photoresist pattern 260 and the plating conductive layer 220 formed outside the hole 205 may be removed from the preliminary semiconductor substrate 200. A backside of the preliminary semiconductor substrate 200 may be etched to form a semiconductor substrate 200a. The preliminary semiconductor substrate 200 may be etched such that the TSV 250 protrudes from the semiconductor substrate 200a. Etching the backside of the preliminary semiconductor substrate 200 may include performing a chemical mechanical polishing (CMP) process and a wet etching process. The CMP process may be performed prior to the wet etching process in order to reduce processing time.

The insulating layer 210 and the plating conductive layer 220 contacting the protruding TSV 250 may be etched to form an insulating pattern 210a and a plating conductive pattern 220a. The plating conductive layer 220 may have an etch selectivity with respect to the TSV 250. If the plating conductive layer 220 has an etch selectivity with respect to the TSV 250, the plating conductive layer 220 may be etched while etching of the TSV 250 is minimal or vice-versa.

A bonding metal layer 270 may be formed on the TSV 250. The bonding metal layer 270 may be formed of an eutectic metal or mixture (e.g., SnAgCu, InAu or the like). The bonding metal layer 270 may electrically connect TSVs 250 of chip packages to each other.

Referring to FIG. 3F, semiconductor chip packages including the TSV 250 may be stacked. The TSV 250 may be electrically connected to a bonding pad (not shown) of the semiconductor chip package. The TSVs 250 of the semiconductor chip packages may be connected to each other via the bonding metal layer 270. Because the bonding metal layer 270 is formed of an eutectic metal having a low melting point, the semiconductor chip packages may be stacked at a substantially low processing temperature.

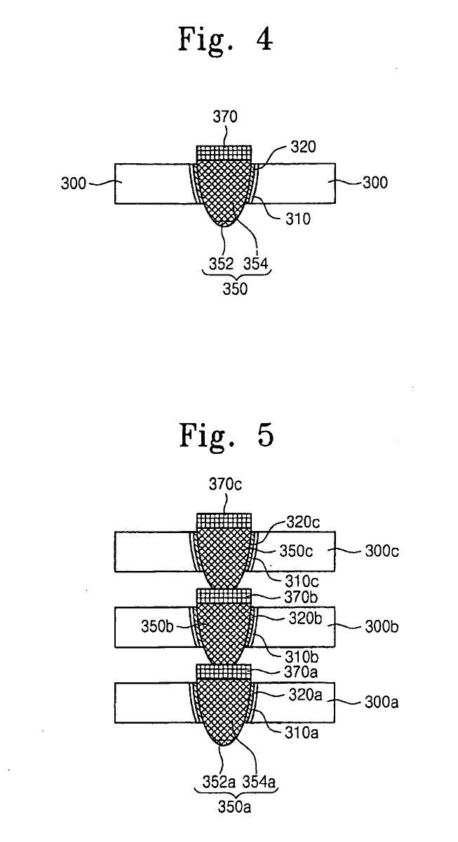

FIGS. 4 and 5 are diagrams illustrating sectional views of a semiconductor device according to example embodiments.

Referring to FIG. 4, a through-silicon via (TSV) 350 penetrates through a semiconductor substrate 300 such that the TSV 350 protrudes from a bottom surface of the semiconductor substrate 300. The TSV 350 includes a seed metal layer 352 and a growth layer 354 grown from the seed metal layer 352. The seed metal layer 352 may include copper, nickel or gold.

An insulating pattern 310 may be provided (or formed) between the TSV 350 and the semiconductor substrate 300. The insulating pattern 310 may include silicon nitride, silicon oxide, polymer or tantalum nitride. A plating conductive pattern 320 may be provided between the insulating pattern 310 and the TSV 350. A bonding metal layer 370 may be provided on the TSV 350. The bonding metal layer 370 may include an eutectic metal or mixture (e.g., SnAgCu, InAu or the like). The growth layer 354 of the TSV 350 may not have a void because the growth layer 354 is grown from the seed metal layer 352, increasing the electrical properties of the semiconductor device.

Referring to FIG. 5, semiconductor chip packages including TSVs 350a, 350b and 350c may be stacked. The TSVs 350a, 350b and 350c may be electrically connected to bonding pads of semiconductor chips (not shown). The semiconductor chip packages may be electrically interconnected by the TSVs 350a, 350b and 350c. Each semiconductor chip package may include the TSVs 350a, 350b and 350c, insulating patterns 310a, 310b and 310c, plating conductive pattern 320a, 320b and 320c, and bonding metal layers 370a, 370b and 370c.

According to example embodiments, a growth layer may grow from a lower portion to an upper portion of a hole. Therefore, a void and a recessed top surface C may not form on the through-silicon via (TSV), increasing electrical properties of a semiconductor chip.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. A semiconductor device, comprising:
a through-silicon via (TSV) penetrating a semiconductor substrate such that the through-silicon via protrudes from a bottom surface of the semiconductor substrate, wherein the through-silicon via (TSV) includes a seed metal layer at a lower portion thereof;
an insulating pattern between the through-silicon via (TSV) and the semiconductor substrate; and
a plating conductive pattern between the insulating pattern and the through-silicon via (TSV).

2. The semiconductor device of claim 1, further comprising a bonding metal layer on the through-silicon via (TSV).

3. The semiconductor device of claim 1, wherein the insulating pattern includes silicon nitride.

4. The semiconductor device of claim 1, wherein the seed metal layer includes at least one selected from the group consisting of copper, nickel and gold.

5. A method for forming a semiconductor device, comprising:
forming a hole in a preliminary semiconductor substrate;
forming an insulating layer in the hole of the preliminary semiconductor substrate;
forming a plating conductive layer on the insulating layer and the preliminary semiconductor substrate;
forming a seed metal layer contacting the plating conductive layer at a lower portion of the hole; and
growing the seed metal layer to form a through-silicon via (TSV).

6. The method of claim 5, wherein forming the seed metal layer at the lower portion of the hole includes:
forming a lift-off resist layer on the plating conductive layer;
forming a photoresist layer on the lift-off resist layer;
patterning the lift-off resist layer and the photoresist layer to form a lift-off resist pattern and a photoresist pattern, respectively, wherein the lift-off resist pattern and the photoresist pattern expose the hole; and
forming the seed metal layer on the photoresist pattern.

7. The method of claim 6, wherein the photoresist pattern and the lift-off resist pattern have an opening with a smaller width than the hole.

8. The method of claim 6, wherein forming the seed metal layer at a lower portion of the exposed hole includes using a sputtering process.

9. The method of claim 6, further comprising removing the lift-off resist pattern after the forming of the seed metal layer.

10. The method of claim 9, wherein removing the lift-off resist pattern includes:
removing the photoresist pattern; and
removing the seed metal layer on the photoresist pattern.

11. The method of claim 5, wherein forming the seed metal layer at the lower portion of the hole includes:
forming a preliminary seed metal layer on the plating conductive layer; and
performing a spin etching process on the preliminary seed metal layer.

12. The method of claim 11, wherein performing the spin etching process includes using an etchant having an etch selectivity with respect to the preliminary seed metal layer.

13. The method of claim 5, wherein the through-silicon via (TSV) is formed by performing an electroplating process to grow the seed metal layer from the lower portion of the hole to an upper portion of the hole.

14. The method of claim 5, further comprising:
etching a backside of the preliminary semiconductor substrate to form a semiconductor substrate with the through-silicon via (TSV) protruding from the semiconductor substrate, after forming the through-silicon via (TSV); and
etching the insulating layer and the plating conductive layer contacting the protruded through-silicon via (TSV) to form an insulating pattern and a plating conductive pattern.

15. The method of claim 14, wherein the plating conductive layer has an etch selectivity with respect to the through-silicon via (TSV).

16. The method of claim 14, further comprising forming a bonding metal layer on the through-silicon via (TSV).
